(19) United States
(12) Patent Application Publication
(10) Pub. No.: US 2026/0150726 A1
(43) Pub. Date: May 28, 2026

(54) RECESSED THROUGH GLASS VIA STRUCTURE FOR GLASS SUBSTRATE

(71) Applicant: Intel Corporation, Santa Clara, CA (US)

(72) Inventor: Yonggang LI, Chandler, AZ (US)

(21) Appl. No.: 18/961,870

(22) Filed: Nov. 27, 2024

(51) Int. Cl. H01L 23/498; H01L 23/15

(52) U.S. Cl. CPC H10W 70/635; H10W 70/692

(57) ABSTRACT

Embodiments disclosed herein include an apparatus that includes a glass substrate with a first surface and a second surface opposite from the first surface. In an embodiment, an opening is provided through a thickness of the substrate, and a first via is in the opening. In an embodiment, a first layer is on the first surface, where the first layer fills a first portion of the opening adjacent to the first via. In an embodiment, a second via is through the first layer in the opening, and the second via is electrically coupled to the first via. In an embodiment, a second layer is on the second surface, and the second layer fills a second portion of the opening adjacent to the first via. In an embodiment, a third via is through the second layer in the opening, and the third via is electrically coupled to the first via.

### BACKGROUND

Glass cores for package substrates are an attractive option due to the increased stiffness, planarity, and routing density that they provide compared to existing organic cores. However, the brittle nature of glass provides several challenges with respect to manufacturing. One issue that is present for glass cores is the high stress that is generated by vias that are formed through the glass core (i.e., through glass vias (TGVs)). With traditional plating, a seed layer is provided along the sidewalls of the via opening, and the via is plated out from the sidewalls. This provides a strong mechanical coupling between the vias and the glass core. During thermal cycling, the via expands more than the glass core, and this generates a high stress in the glass core. The high stress may result in cracking or other defects that significantly impact the reliability of the glass core.

### BRIEF DESCRIPTION OF THE DRAWINGS

FIG. 1 is a cross-sectional illustration of a portion of a glass core and through glass via (TGV) that illustrates a high-stress region at a corner interface between the glass core and the TGV, in accordance with an embodiment.

FIG. 2A is a cross-sectional illustration of a portion of a glass core and a TGV with a recessed structure where a buffer layer lines a corner interface between the glass core and the TGV, in accordance with an embodiment.

FIG. 2B is a cross-sectional illustration of the glass core in FIG. 2A that depicts the entirety of the TGV, in accordance with an embodiment.

FIG. 2C is a cross-sectional illustration of a glass core with a via opening that has an hourglass shaped profile, in accordance with an embodiment.

FIGS. 3A-3G are cross-sectional illustrations that depict a process for forming a TGV with a sintering process in a package substrate that provides a dielectric layer over a corner interface between the glass core and the TGV, in accordance with an embodiment.

FIGS. 4A-4C are cross-sectional illustrations that depict an iterative sintering process to form the TGV, in accordance with an embodiment.

FIG. 5 is a flow diagram of a process for forming a TGV in a glass core with a sintering process, in accordance with an embodiment.

FIG. 6 is a cross-sectional illustration of an electronic system that comprises a package substrate with a glass core that includes a TGV that is formed with a sintering process, in accordance with an embodiment.

FIG. 7 is a schematic of a computing device built in accordance with an embodiment.

### EMBODIMENTS OF THE PRESENT DISCLOSURE

Described herein are glass substrates with through glass vias (TGVs) that are formed with a sintering process, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide improved stiffness, planarity, and routing density compared to organic cores. However, the strong mechanical coupling between the through glass vias (TGVs) and the glass core results in significant stress being induced in the glass core during thermal cycling. As such, cracking or other damage to the glass core may occur. This negatively impacts the reliability of such glass cores. Further, the high aspect ratios of the TGVs make it difficult to form void-free TGVs in a cost-effective manner. For example, an atomic layer deposition process may be used for seeding the TGV sidewalls followed with electrolytic plating with delicate engineering around plating dynamics at different locations of the TGV geometry and the plating stage. However, atomic layer deposition is a slow and expensive process, and such a process may not be affordable with high volume manufacturing environments. The sidewall driven electrolytic plating becomes challenging as the TGV aspect ratio (height:diameter) reaches approximately 10:1 or greater. Further, the process quality is highly sensitive to the sidewall profile of the TGV.

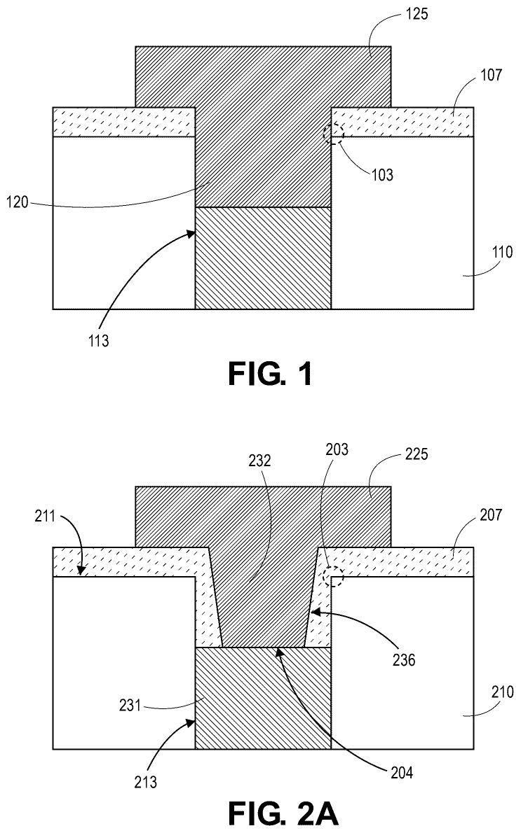

The stress applied to the glass core may be highest at sharp edges between the TGV and the glass core. For example, the corner of the glass core at the edge of the opening in which the TGV is formed is often a source of cracking or other defects in the glass core. An example of such a TGV is shown in FIG. 1.

Referring now to FIG. 1, a cross-sectional illustration of a glass core 110 with a portion of a TGV 120 (i.e., the top half of the TGV 120) is shown, in accordance with an embodiment. As shown, the TGV 120 may extend through an opening in the glass core 110 that is defined by sidewalls 113. A buffer layer 107 may be provided over the top surface of the glass core 110. The TGV 120 may pass through the buffer layer 107 in order to contact an overlying pad 125. As indicated by the dashed circle, a corner region 103 is an interface where multiple different materials contact each other at a single point. For example, in FIG. 1 the glass core 110, the TGV 120, and the buffer layer 107 meet at the corner region 103. The different materials have different coefficients of thermal expansion (CTE). This results in large stresses being formed during thermal cycling due to uneven expansion between the three materials. The uneven expansion at a sharp corner region 103 can lead to high stress concentrations within the glass core 110. The high stress concentrations may lead to cracking and/or other damage within the glass core 110. In other instances, the overlying pad 125 may also be in direct contact with the glass core 110. That is, the buffer layer 107 surrounds a perimeter of the overlying pad 125. In such an embodiment, the stress induced at the corner region 103 can be even more severe.

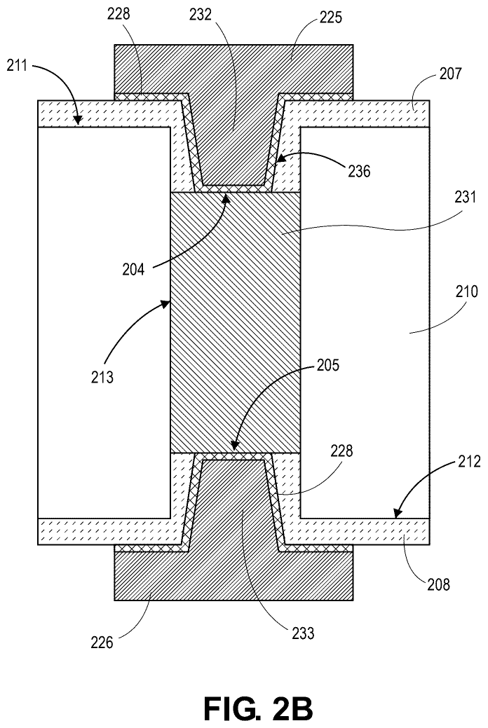

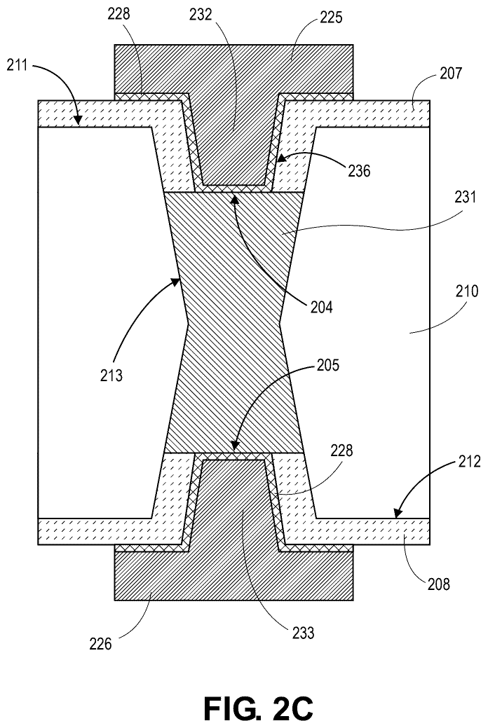

Accordingly, embodiments disclosed herein may include the formation of TGVs that include a recessed surface that allows for a buffer layer to line the corner region at the opening through the glass core. For example, a first portion of the via is formed with a sintering process that allows for a volumetric reduction of the first portion of the via within the via opening. A buffer layer (e.g., an organic dielectric material) fills a remainder of the via opening, and a second portion of the via is formed through a thickness of the buffer layer. An example of such TGV is shown in FIG. 2A.

Referring now to FIG. 2A, a cross-sectional illustration of a portion of a glass core 210 is shown, in accordance with an embodiment. In an embodiment, a via opening defined by sidewalls 213 is provided through a thickness of the glass core 210. The via opening may be formed with any suitable process. For example, a laser assisted etching process may be used to form the via opening in some embodiments. In an embodiment, the via opening may be a high aspect ratio via opening. For example, an aspect ratio (height: diameter) of the via opening may be 5:1 or greater, 10:1 or greater, or 20:1 or greater. Though, embodiments may also be used with smaller aspect ratio via openings as well.

In an embodiment, the glass core 210 may be substantially all glass. The glass core 210 may be a solid mass comprising a glass material with an amorphous crystal structure where the solid glass core may also include various structures - such as vias, cavities, channels, or other features - that are filled with one or more other materials (e.g., metals, metal alloys, dielectric materials, etc.). As such, glass core 210 may be distinguished from, for example, the “prepreg” or “FR4” core of a Printed Circuit Board (PCB) substrate which typically comprises glass fibers embedded in a resinous organic material, such as an epoxy.

The glass core 210 may have any suitable dimensions. In a particular embodiment, the glass core 210 may have a thickness that is approximately 50 μm or greater. For example, the thickness of the glass core 210 may be between approximately 50 μm and approximately 1.4 mm. Though, smaller or larger thicknesses may also be used. The glass core 210 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 210 (from an overhead plan view) may be between approximately 10 mm×10 mm and approximately 250 mm×250 mm. In an embodiment, the glass core 210 may have a first side that is perpendicular or orthogonal to a second side. In a more general embodiment, the glass core 210 may comprise a rectangular prism volume with sections (e.g., vias) removed and filled with other materials (e.g., metal, etc.).

The glass core 210 may comprise a single monolithic layer of glass. In other embodiments, the glass core 210 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 210 may each have a thickness less than approximately 50 μm. For example, discrete layers of glass in the glass core 210 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 210 may be any suitable glass formulation that has the necessary mechanical robustness and compatibility with semiconductor packaging manufacturing and assembly processes. For example, the glass core 210 may comprise aluminosilicate glass, borosilicate glass, alumino-borosilicate glass, silica, fused silica, or the like. In some embodiments, the glass core 210 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 210 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 210 may comprise at least 23 percent silicon (by weight) and at least 26 percent oxygen (by weight). In some embodiments, the glass core 210 may further comprise at least 5 percent aluminum (by weight).

In FIG. 2A a portion of the TGV (i.e., an upper portion) is shown, in accordance with an embodiment. In an embodiment, the TGV may comprise a first via portion 231 and a second via portion 232. The first via portion 231 may have a surface 204 that is recessed below a top surface 211 of the glass core 210. The first via portion 231 may be entirely within the via opening. The second via portion 232 may pass through a buffer layer 207 that is over the top surface 211 of the glass core 210, and the second via portion 232 extends into the via opening. The second via portion 232 may be electrically coupled to the first via portion 231. For example, in FIG. 2A the first via portion 231 directly contacts the second via portion 232. Though, as will be described in greater detail herein, a seed layer or any other intervening electrically conductive layer may be provided between the first via portion 231 and the second via portion 232.

In an embodiment, the buffer layer 207 may also fill a portion of the via opening. The second via portion 232 may pass through a portion of the buffer layer 207 within the via opening. That is, the second via portion 232 may be surrounded by the buffer layer 207 so that the second via portion 232 is separated from the sidewalls 213 of the via opening by the buffer layer 207. In contrast, the first via portion 231 may directly contact the sidewalls 213 of the via opening. Stated differently, the first via portion 231 may directly contact the glass core 210, and the second via portion 232 may be separated from the glass core 210 by the buffer layer 207.

In an embodiment, the sidewall 236 of the second via portion 232 may be sloped relative to the top surface 211 of the glass core 210. In an embodiment, the slope of the sidewall 236 may be the result of a patterning process used to form an opening through the buffer layer 207. For example, a laser ablation process may be used to form the opening through the buffer layer 207. In an embodiment, a pad 225 may be provided over the buffer layer 207 and electrically coupled to the second via portion 232.

As shown, the corner region 203 of the glass core 210 where the via opening sidewall 213 meets the top surface 211 of the glass core 210 is covered by the buffer layer 207. This allows for the second via portion 232 to be spaced away from the corner region 203. The buffer layer 207 may comprise a polymer material, a polymer-based composite, or the like. In an embodiment, the buffer layer 207 may have a lower mechanical modulus as compared to a mechanical modulus of the first via portion 231 and/or the second via portion 232. It can absorb stress induced by the second via portion 232. Accordingly, stress concentrations at the corner region 203 are reduced. This improves the mechanical robustness of the glass core 210 since the glass core 210 is less likely to crack during thermal cycling.

In an embodiment, the first via portion 231 may have a first porosity, and the second via portion 232 may have a second porosity that is different than the first porosity. For example, a porosity of the first via portion 231 may be higher than a porosity of the second via portion 232. The difference in porosity may be the result of different processes used to form the first via portion 231 and the second via portion 232. For example, the first via portion 231 may be formed with a sintering process, and the second via portion 232 may be formed with an electrolytic plating process. The porosity of a material may refer to an area of a cross-section that comprises solid material relative to an area of the cross-section that comprises voids, gaps (e.g., air gaps), or the like. In an embodiment, the first via portion 231 may have a porosity that is approximately 20% or less (i.e., approximately 20% or less of an area of the of the cross-section comprises voids or gaps, and approximately 80% or more of an area of the cross-section comprises a solid material). Though, embodiments may include a first via portion 231 that has a porosity that is approximately 10% or less, approximately 5% or less, or approximately 1% or less. The second via portion 232 may have a porosity that is approximately 5% or less, approximately 1% or less, or approximately 0.5% or less.

Referring now to FIG. 2B, a cross-sectional illustration of a glass core 210 is shown, in accordance with an embodiment. The glass core 210 in FIG. 2B may be similar to the glass core 210 described with respect to FIG. 2A. However, the full height of the TGV is shown in FIG. 2B. As shown, the glass core 210 may comprise a bottom surface 212, and the first via portion 231 may have a surface 205 that is recessed from the bottom surface 212 of the glass core 210. Similar to the top end of the TGV, a buffer layer 208 may partially fill a portion of the via opening, and a third via portion 233 may pass through the buffer layer 208. That is, the buffer layer 208 may separate the third via portion 233 from the glass core 210 in order to reduce stress in the glass core 210.

In an embodiment, the first via portion 231 may have a height (between the surface 204 and the surface 205) that is less than a thickness of the glass core 210 between the top surface 211 and the bottom surface 212. In an embodiment, the first via portion 231 may have a midpoint between the surface 204 and the surface 205, and the glass core 210 may have a midpoint between the top surface 211 and the bottom surface 212. A line connecting the midpoint of the first via portion 231 and the midpoint of the glass core 210 may be substantially parallel to the top surface 211 of the glass core in some embodiments.

In the illustrated embodiment, the sidewalls 213 of the via opening are substantially vertical (i.e., orthogonal to the top surface 211 and the bottom surface 212 of the glass core 210). Though, embodiments may also include sidewalls 213 that are tapered or have any other profile, as will be described in greater detail herein. In an embodiment a width of the first via portion 231 may be wider than a width of the second via portion 232 and the third via portion 233.

In FIG. 2B, a seed layer 228 is shown between the second via portion 232 and the buffer layer 207 as well as between the third via portion 233 and the buffer layer 208. The seed layers 228 may be used to plate the second via portion 232, the pad 225, the third via portion 233, and a pad 226. For example, an electrolytic plating process may be used to plate the second via portion 232, the pad 225, the third via portion 233, and the pad 226. In some embodiments, a portion of the seed layer 228 may separate the first via portion 231 from the second via portion 232, and a portion of the seed layer 228 may separate the first via portion 231 from the third via portion 233. Further, the seed layer 228 may separate the second via portion 232 from the buffer layer 207, and the seed layer 228 may separate the third via portion 233 from the buffer layer 208. Due to the use of plating processes, both the second via portion 232 and the third via portion 233 may have lower porosities than the first via portion 231 (which may be formed with a sintering process).

Referring now to FIG. 2C, a cross-sectional illustration of a glass core 210 is shown, in accordance with an additional embodiment. The glass core 210 in FIG. 2C may be similar to the glass core 210 in FIG. 2B, with the exception of the profile of the sidewalls 213. For example, the sidewalls 213 in FIG. 2C may be sloped with respect to the top surface 211 of the glass core 210 and/or the bottom surface 212 of the glass core 210. In the particular embodiment shown in FIG. 2C, the sidewalls 213 may form an hourglass shaped via opening profile. Though, in other embodiments, the sidewalls 213 may form a via opening with a single taper (e.g., the via opening may be wider at the top surface 211 of the glass core 210 than the bottom surface 212 of the glass core). In some embodiments, the first via portion 231 may have a non-uniform diameter through the height of the first via portion 231.

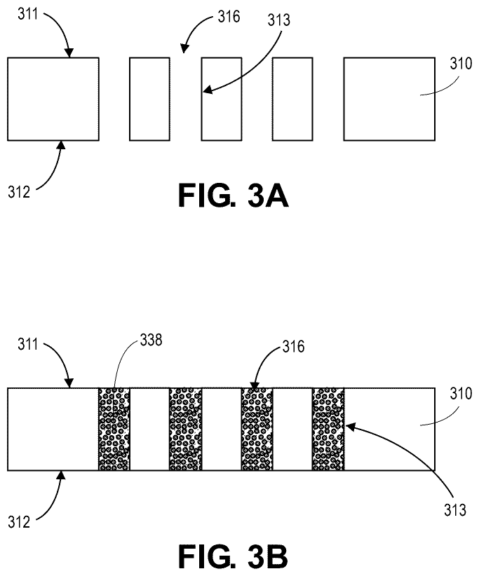

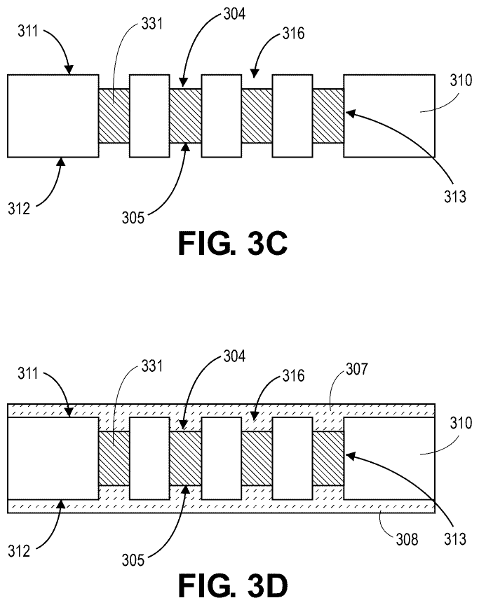

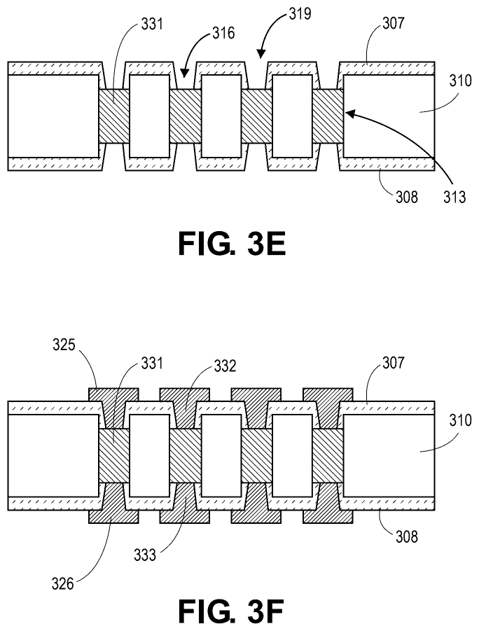

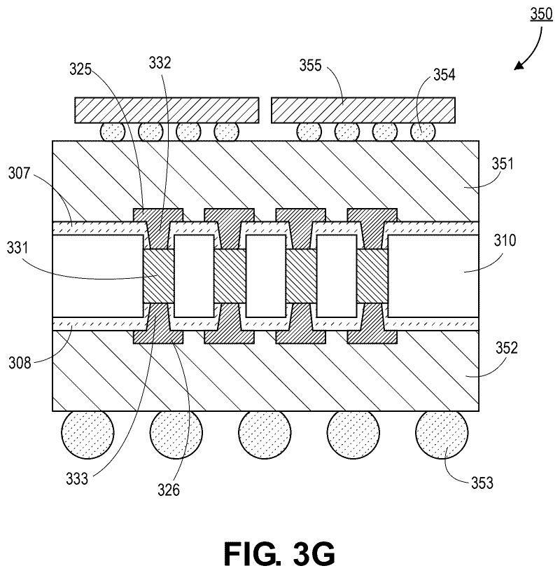

Referring now to FIGS. 3A-3G, a series of cross-sectional illustrations depicting a process for forming a package substrate with a glass core that includes TGVs that are formed with a sintering process is shown, in accordance with an embodiment.

Referring now to FIG. 3A, a cross-sectional illustration of a glass core 310 is shown, in accordance with an embodiment. In an embodiment, the glass core 310 may be similar to any of the glass cores or glass substrates describe in greater detail herein. In the illustrated embodiment, a single glass core 310 unit is shown. Though, it is to be appreciated that a glass panel or glass substrate with a plurality of glass core 310 units may be used in accordance with similar embodiments. In an embodiment, the glass core 310 may comprise a top surface 311 and a bottom surface 312. A plurality of via openings 316 may be formed through a thickness of the glass core 310. In the illustrated embodiment, the sidewalls 313 of the via openings 316 are substantially vertical. Though, it is to be appreciated that the sidewalls 313 may be sloped with respect to the top surface 311 or the bottom surface 312 in some embodiments. The via openings 316 may be formed with any suitable patterning process, such as a laser assisted etching process. In an embodiment, the via openings 316 may have an aspect ratio (height:diameter) that is approximately 5:1 or greater, approximately 10:1 or greater, or approximately 20:1 or greater. Though via openings 316 with smaller aspect ratios may also benefit from embodiments described herein.

Referring now to FIG. 3B, a cross-sectional illustration of the glass core 310 after a conductive nano-paste 338 is dispensed into the via openings 316 is shown, in accordance with an embodiment. In an embodiment, the nano-paste 338 may comprise a copper-based nano-paste material. The nano-paste 338 may be dispensed into the via openings 316 with a printing process (e.g., a screen printing process, a stencil printing process, or the like). In an embodiment, the nano-paste 338 may substantially fill the via openings 316.

Referring now to FIG. 3C, a cross-sectional illustration of the glass core 310 after the nano-paste 338 is sintered to form a first via portion 331 is shown, in accordance with an embodiment. As shown, the sintering process may result in a volumetric reduction in the nano-paste 338 so that the solid first via portion 331 has a top surface 304 that is recessed from the top surface 311 of the glass core 310 and a bottom surface 305 that is recessed from the bottom surface 312 of the glass core 310. That is, portions of the via openings 316 above and below each first via portion 331 are empty.

In an embodiment, the sintering process may be designed to provide low porosities for the first via portions 331. For example, a temperature of the sintering process may be approximately 250° C. or higher, or approximately 350° C. or higher. In some embodiments, the sintering process may be implemented in a reductive environment (e.g., with exposure to hydrogen, formic acid, or the like). In an embodiment, the first via portions 331 may have porosities that are approximately 10% or less, approximately 5% or less, or approximately 1% or less.

Referring now to FIG. 3D, a cross-sectional illustration of the glass core 310 after a buffer layer 307 is applied over the top surface 311 and a buffer layer 308 is applied over the bottom surface 312 is shown, in accordance with an embodiment. In an embodiment, the buffer layers 307 and 308 may comprise organic dielectric material, such as organic buildup material. The buffer layers 307 may be applied with a liquid process, a film lamination process, or the like.

As shown, the buffer layers 307 and 308 may fill portions of the via openings 316 above and below the first via portions 331. That is, the buffer layers 307 and 308 may directly contact the first via portions 331 in some embodiments. However, it is to be appreciated that there may not be a buffer layer (or any other intervening layer) between sidewalls of the first via portions 331 and the sidewalls 313 of the glass core 310. That is, the first via portions 331 may directly contact the glass core 310 in some embodiments.

Referring now to FIG. 3E, a cross-sectional illustration of the glass core 310 after buffer layer openings 319 are formed through the buffer layers 307 and 308 is shown, in accordance with an embodiment. The buffer layer openings 319 may be formed with a laser ablation process or any other suitable subtractive patterning process. The formation of the buffer layer openings 319 may not remove an entirety of the buffer layers 307 and 308 from the via openings 316. That is, the buffer layer openings 319 may be narrower than the via openings 316.

Referring now to FIG. 3F, a cross-sectional illustration of the glass core 310 after second via portions 332, pads 325, third via portions 333, and pads 326 are formed is shown, in accordance with an embodiment. In an embodiment, the second via portions 332, pads 325, third via portions 333, and pads 326 may be formed with a plating process, such as an electrolytic plating process. While not shown, a seed layer may be formed over the buffer layers 307 and 308 in order to allow for the plating. For example, seed layers similar to seed layers 228 described above may be used for the plating process. Due to the use of a plating process, the second via portions 332 and the third via portions 333 may have porosities that are lower than the porosity of the first via portion 331. Further, while shown as having different shadings in FIG. 3F, it is to be appreciated that the first via portions 331, the second via portions 332, and the third via portions 333 may comprise substantially the same composition. For example, the first via portions 331, the second via portions 332, and the third via portions 333 may comprise substantially copper in some embodiments.

Referring now to FIG. 3G, a cross-sectional illustration of a package substrate 350 that comprises the glass core 310 is shown, in accordance with an embodiment. In an embodiment, the glass core 310 may be covered by a top buildup layer 351 over the buffer layer 307 and a bottom buildup layer 352 over the buffer layer 308. In an embodiment, the top buildup layer 351 and the bottom buildup layer 352 may each comprise a plurality of laminated organic layers (e.g., buildup film layers). In some embodiments, the top buildup layer 351 and the bottom buildup layer 352 may comprise the same material as the buffer layers 307 and 308. In an embodiment, electrically conductive routing (not shown) within the top buildup layer 351 may electrically couple the pads 325 to first level interconnects (FLIs) 354, and electrically conductive routing (not shown) within the bottom buildup layer 352 may electrically couple the pads 326 to second level interconnects (SLIs) 353. The electrically conductive routing may include pads, traces, vias, and/or the like. In an embodiment, one or more dies 355 may be electrically coupled to the top buildup layer 351 by the FLIs 354. In some embodiments, a bridge substrate (not shown) that is embedded within the top buildup layer 351 or provided over the top buildup layer 351 may electrically couple two or more dies 355 together.

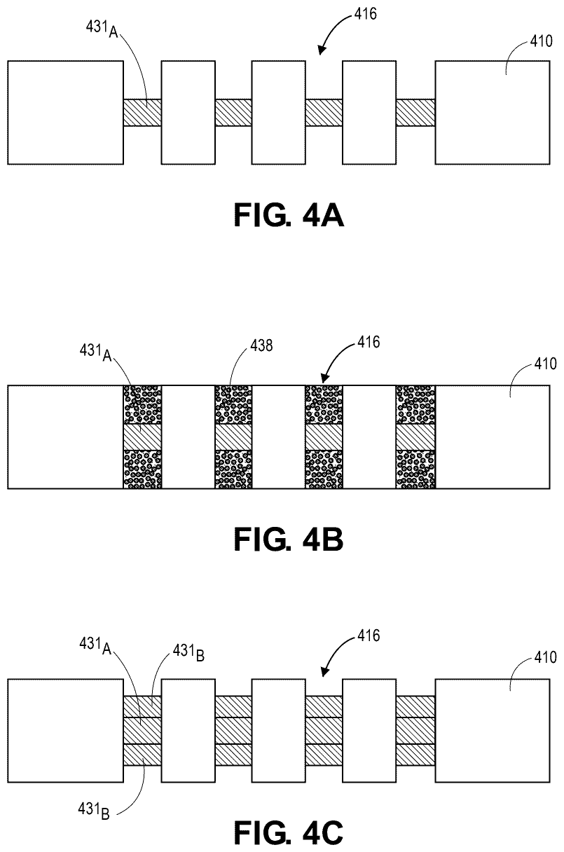

Referring now to FIGS. 4A-4C , a series of cross-sectional illustrations that depict an alternative process for forming the first via portion of the TGV within a glass core is shown, in accordance with an embodiment.

Referring now to FIG. 4A, a cross-sectional illustration of a glass core 410 with sintered first via portions 431_{A} within via openings 416 is shown, in accordance with an embodiment. The glass core 410 and first via portions 431_{A} in FIG. 4A may be similar to the glass core 310 and first via portions 331 in FIG. 3C, with the exception of the height of the first via portions 431_{A}. For example, the sintering process may result in a greater volumetric reduction of the first via portions 431_{A}. In such an embodiment, the empty portions of the via openings 416 may be too large. Accordingly, an iterative sintering process may be used.

Referring now to FIG. 4B, a cross-sectional illustration of the glass core 410 after conductive nano-paste 438 is dispensed into the via openings 416 over the first via portions 431_{A}. The nano-paste 438 may be dispensed with a screen printing process, a stencil printing process, or the like.

Referring now to FIG. 4C, a cross-sectional illustration of the glass core 410 after a sintering process is used to form first via portions 431_{B} over and under the first via portions 431_{A} is shown, in accordance with an embodiment. The sintering process in FIG. 4C may be similar to any of the sintering processes described in greater detail herein. The volumetric reduction of the first via portions 431_{B} may result in the desired recess relative to a top and bottom of the via openings 416. Though, in other embodiments, more than two nano-paste deposition and sintering cycles may be used. In embodiments that comprise a plurality of sintering cycles, seams may be visible within the first via portion (i.e., the first via portions 431_{A} and 431_{B}) as shown in FIG. 4C.

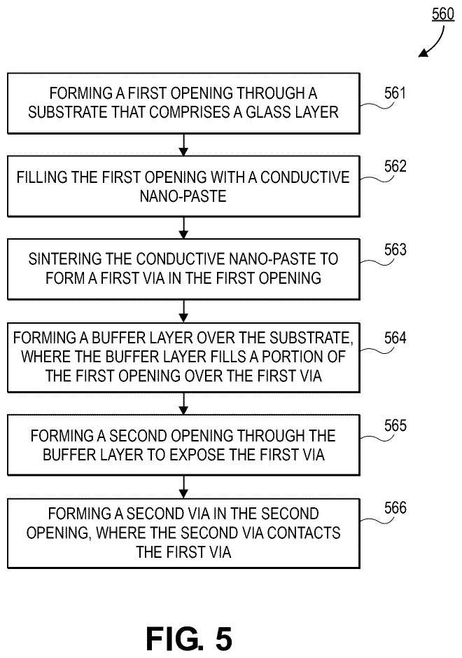

Referring now to FIG. 5, a flow diagram that depicts a process 560 for forming TGVs in a glass core with a sintering process is shown, in accordance with an embodiment. In an embodiment, the process 560 may be similar to the any of the sintering processes described in greater detail. For example, the TGVs may have sintered region with recessed top and bottom surfaces and a plated region that passes through a buffer layer.

In an embodiment, the process 560 may begin with operation 561, which comprises forming a first opening through a substrate that comprises a glass layer. In an embodiment, the substrate may be similar to any of the glass cores described in greater detail herein. In an embodiment, the first opening may be considered a via opening. The first opening may be formed with any suitable patterning process, such as a laser assisted etching process or the like.

In an embodiment, the process 560 may continue with operation 562, which comprises filling the first opening with a conductive nano-paste. In an embodiment, the conductive nano-paste may comprise copper nanoparticles or the like. The conductive nano-paste may be dispensed into the first opening with a screen printing process, a stencil printing process, or the like.

In an embodiment, the process 560 may continue with operation 563, which comprises sintering the conductive nano-paste to form a first via in the first opening. In an embodiment, the sintering process may result in the formation of the first via that is recessed from the top and bottom of the first opening. The sintering process may be similar to any of the sintering processes described in greater detail herein. For example, the sintering temperature may be approximately 250° C. or higher or approximately 350° C. or higher. In some embodiments, the sintering process may be implemented in a reductive environment (e.g., with exposure to hydrogen, formic acid, or the like).

In an embodiment, operation 562 and 563 may be repeated any number of times in order to provide a first via with the desired dimensions within the first opening. For example, a cyclical nano-paste dispense and sintering process may be repeated a plurality of times similar to the embodiment described with respect to FIGS. 4A-4C.

In an embodiment, the process 560 may continue with operation 564, which comprises forming a buffer layer over the substrate. In an embodiment, the buffer layer fills a portion of the first opening over the first via. The buffer layer may comprise an organic dielectric material or the like. The buffer layer may be applied with liquid process, a lamination process, or the like.

In an embodiment, the process 560 may continue with operation 565, which comprises forming a second opening through the buffer layer to expose the first via. In an embodiment, the second opening may be formed with a laser drilling process, or any other suitable subtractive patterning process. In an embodiment, a width of the second opening may be narrower than a width of the first opening. As such, a portion of the buffer layer may remain within the first opening after the second opening is formed.

In an embodiment, the process 560 may continue with operation 566, which comprises forming a second via in the second opening. In an embodiment, the second via is electrically coupled to the first via. In an embodiment, the second via may be formed with an electrolytic plating process or the like. For example, a seed layer may be formed over the buffer layer in order to plate up the second via. Due to the different processes used to form the first via and the second via, the porosities of the first via and the second via may be different. For example, the first via may have a higher porosity than the second via.

In an embodiment, the resulting substrate may then be integrated into a package substrate through typical buildup layer manufacturing processes. For example, a plurality of laminated layers are patterned to form electrical routing. The electrical routing in the buildup layers may electrically couple the second via to a die coupled to the package substrate in some embodiments.

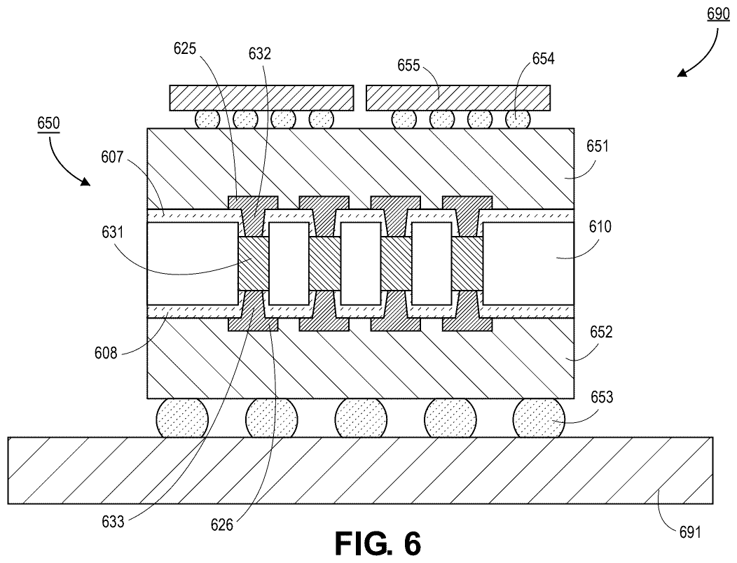

Referring now to FIG. 6, a cross-sectional illustration of an electronic system 690 is shown, in accordance with an embodiment. In an embodiment, the electronic system 690 may comprise a board 691, such as a printed circuit board (PCB), a motherboard, or the like. In an embodiment, the board 691 may be coupled to a package substrate 650 by SLIs 653. In an embodiment, the SLIs 653 may comprise solder balls, sockets, or the like.

In an embodiment, the package substrate 650 may be similar to any of the package substrates described in greater detail herein. In an embodiment, the package substrate 650 may comprise a glass core 610 with TGVs. In an embodiment, the TGVs may comprise a first via portion 631 with a second via portion 632 over the first via portion 631 and a third via portion 633 under the first via portion 631. The second via portion 632 and the third via portion 633 may be spaced away from the glass core 610 by a portion of buffer layers 607 and 608, respectively. Though, the TGV structure of the glass core 610 may be similar to any of the TGV structures described in greater detail herein.

In an embodiment, the package substrate 650 may also comprise buildup layers 651 and 652 that are provided over and under the glass core 610. The buildup layer 651 may include electrical routing (not shown) to electrically couple pads 625 to FLIs 654, and the buildup layer 652 may include electrical routing (not shown) to electrically couple pads 626 to SLIs 653.

In an embodiment, one or more dies 655 may be coupled to the buildup layer 651 by FLIs 654. The FLIs 654 may be any suitable FLI architecture, such as solder balls, copper bumps, hybrid bonding interfaces, or the like. In an embodiment, the one or more dies 655 may be any type of die (e.g., a processor die (e.g., a central processing unit (CPU), a graphics processing unit (GPU), an XPU), a memory die, a communications die, a power management die, and/or the like). In an embodiment, two or more dies 655 may be electrically coupled together by a bridge (not shown) that is embedded in the buildup layer 651 or provided over the buildup layer 651.

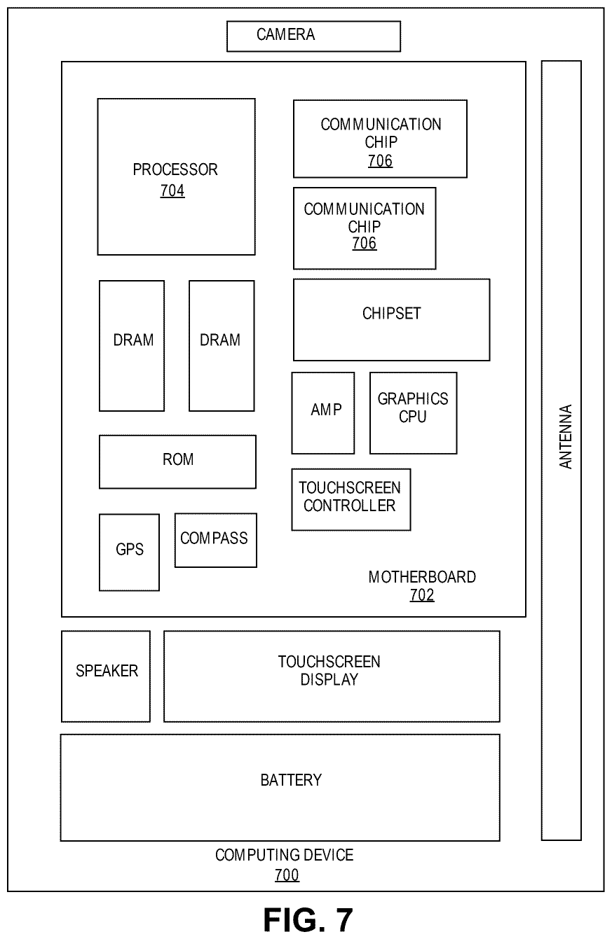

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of a package substrate with a glass core that comprises TGVs that are formed with a sintering process, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of a package substrate with a glass core that comprises TGVs that are formed with a sintering process, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first surface and a second surface opposite from the first surface, wherein the substrate comprises a glass layer; an opening through a thickness of the substrate; a first via with a third surface and a fourth surface opposite from the third surface in the opening; a first layer on the first surface, wherein the first layer fills a first portion of the opening adjacent to the third surface of the first via; a second via through the first layer in the opening, wherein the second via is electrically coupled to the first via; a second layer on the second surface, wherein the second layer fills a second portion of the opening adjacent to the fourth surface of the first via; and a third via through the second layer in the opening, wherein the third via is electrically coupled to the first via.

Example 2: the apparatus of Example 1, wherein the first via has a first porosity, the second via has a second porosity, and the third via has a third porosity, and wherein the first porosity is greater than the second porosity and the third porosity.

Example 3: the apparatus of Example 1 or Example 2, wherein the first via comprises a sintered metal.

Example 4: the apparatus of Examples 1-3, wherein the first layer covers a corner of the substrate at an edge of the opening.

Example 5: the apparatus of Examples 1-4, wherein a sidewall of the opening is sloped with respect to the first surface.

Example 6: the apparatus of Examples 1-5, wherein the first layer contacts the first via, and wherein the second layer contacts the first via.

Example 7: the apparatus of Examples 1-6, wherein the first via directly contacts the substrate.

Example 8: the apparatus of Examples 1-7, wherein the first layer separates the second via from the substrate.

Example 9: the apparatus of Examples 1-8, further comprising: a seed layer between the second via and the first layer.

Example 10: the apparatus of Examples 1-9, wherein the substrate is a core of a package substrate.

Example 11: an apparatus, comprising: a substrate with a thickness between a first surface and a second surface, wherein the substrate comprises a glass layer; an opening through the substrate; a first via in the opening, wherein the first via has a height that is smaller than the thickness of the substrate; a layer over the first surface of the substrate, wherein the layer fills a portion of the opening and contacts the first via; and a second via through the layer, wherein the second via is electrically coupled to the first via.

Example 12: the apparatus of Example 11, wherein the first via has a first porosity and the second via has a second porosity, and wherein the first porosity is greater than the second porosity.

Example 13: the apparatus of Example 12, wherein the first via comprises a sintered metal.

Example 14: the apparatus of Examples 11-13, wherein the first via has a third surface and a fourth surface opposite from the first surface, and wherein the third surface is recessed from the first surface of the substrate and the fourth surface is recessed from the second surface of the substrate.

Example 15: the apparatus of Example 14, wherein a first midpoint between the first surface and the second surface and a second midpoint between the third surface and the fourth surface are both along a line that is substantially parallel to the first surface.

Example 16: the apparatus of Examples 11-15, wherein the second via directly contacts the first via.

Example 17: an apparatus, comprising: a board; a package substrate coupled to the board, wherein the package substrate comprises: a core, wherein the core comprises a glass layer; and an opening through the core, wherein a first via, a second via that is electrically coupled to the first via, and a layer that surrounds the second via are in the opening; and a die coupled to the package substrate.

Example 18: the apparatus of Example 17, wherein the first via has a first porosity and the second via has a second porosity, and wherein the first porosity is greater than the second porosity.

Example 19: the apparatus of Example 17 or Example 18, wherein a third via that is electrically coupled to the first via and a second layer that surrounds the third via are in the opening.

Example 20: the apparatus of Examples 17-19, wherein the layer covers a corner of the core at an edge of the opening.

What is claimed is:

1. An apparatus, comprising:
a substrate with a first surface and a second surface opposite from the first surface, wherein the substrate comprises a glass layer;
an opening through a thickness of the substrate;
a first via with a third surface and a fourth surface opposite from the third surface in the opening;
a first layer on the first surface, wherein the first layer fills a first portion of the opening adjacent to the third surface of the first via;
a second via through the first layer in the opening, wherein the second via is electrically coupled to the first via;
a second layer on the second surface, wherein the second layer fills a second portion of the opening adjacent to the fourth surface of the first via; and
a third via through the second layer in the opening, wherein the third via is electrically coupled to the first via.

2. The apparatus of claim 1, wherein the first via has a first porosity, the second via has a second porosity, and the third via has a third porosity, and wherein the first porosity is greater than the second porosity and the third porosity.

3. The apparatus of claim 1, wherein the first via comprises a sintered metal.

4. The apparatus of claim 1, wherein the first layer covers a corner of the substrate at an edge of the opening.

5. The apparatus of claim 1, wherein a sidewall of the opening is sloped with respect to the first surface.

6. The apparatus of claim 1, wherein the first layer contacts the first via, and wherein the second layer contacts the first via.

7. The apparatus of claim 1, wherein the first via directly contacts the substrate.

8. The apparatus of claim 1, wherein the first layer separates the second via from the substrate.

9. The apparatus of claim 1, further comprising:
a seed layer between the second via and the first layer.

10. The apparatus of claim 1, wherein the substrate is a core of a package substrate.

11. An apparatus, comprising:
a substrate with a thickness between a first surface and a second surface, wherein the substrate comprises a glass layer;
an opening through the substrate;
a first via in the opening, wherein the first via has a height that is smaller than the thickness of the substrate;
a layer over the first surface of the substrate, wherein the layer fills a portion of the opening and contacts the first via; and
a second via through the layer, wherein the second via is electrically coupled to the first via.

12. The apparatus of claim 11, wherein the first via has a first porosity and the second via has a second porosity, and wherein the first porosity is greater than the second porosity.

13. The apparatus of claim 12, wherein the first via comprises a sintered metal.

14. The apparatus of claim 11, wherein the first via has a third surface and a fourth surface opposite from the first surface, and wherein the third surface is recessed from the first surface of the substrate and the fourth surface is recessed from the second surface of the substrate.

15. The apparatus of claim 14, wherein a first midpoint between the first surface and the second surface and a second midpoint between the third surface and the fourth surface are both along a line that is substantially parallel to the first surface.

16. The apparatus of claim 11, wherein the second via directly contacts the first via.

17. An apparatus, comprising:
a board;
a package substrate coupled to the board, wherein the package substrate comprises:
a core, wherein the core comprises a glass layer; and
an opening through the core, wherein a first via, a second via that is electrically coupled to the first via, and a layer that surrounds the second via are in the opening; and
a die coupled to the package substrate.

18. The apparatus of claim 17, wherein the first via has a first porosity and the second via has a second porosity, and wherein the first porosity is greater than the second porosity.

19. The apparatus of claim 17, wherein a third via that is electrically coupled to the first via and a second layer that surrounds the third via are in the opening.

20. The apparatus of claim 17, wherein the layer covers a corner of the core at an edge of the opening.
